(19) United States
(12) Patent Application Publication
(10) Pub. No.: US 2011/0139500 A1
(43) Pub. Date: Jun. 16, 2011

(54) ELECTRICAL CONNECTING METHOD AND ELECTRICALLY CONNECTED CONNECTION STRUCTURE

(76) Inventor: Tomihiro Hara, Tokyo (JP)

(21) Appl. No.: 13/058,946

(22) PCT Filed: Aug. 27, 2009
(86) PCT No.: PCT/US09/55137

§ 371 Date: Feb. 14, 2011

(30) Foreign Application Priority Data
Sep. 2, 2008 (JP) 2008-225091

(51) Int. Cl. H05K 1/11; H05K 3/00

(52) U.S. Cl. 174/259; 174/261; 29/829

(57) ABSTRACT

A method of connecting a flexible flat cable and a board is provided, which includes the steps of preparing the flexible flat cable having a first connection terminal composed of a plurality of exposed flat type conductors; preparing the board having a second connection terminal composed of a plurality of conductors; aligning each of the first and second connection terminals and placing an adhesive film on the first connection terminal; and thermocompressionally bonding the first and second connection terminals by heating and fusing the adhesive film while applying a pressure to the adhesive film, thereby sealing the first and second connection terminals, bringing each flat type conductor of the first connection terminal and the corresponding conductor of the second connection terminal into direct contact to form an electrical connection, and insulating adjacent ones of the plurality of flat type conductors of the first connection terminal by the adhesive film.

### TECHNICAL FIELD

The disclosure hereof relates to a method of electrically connecting an exposed connection terminal of a flat cable or the like and a connection terminal of a board, and to an electrically connected structure.

### BACKGROUND

A flat cable referred to as an FFC (Flexible Flat Cable) and composed of a plurality of conductors, which are arrayed in parallel at intervals and covered with a film coating together, has been used for wiring in various kinds of electric devices. In an electric device, an FFC electrically connects two circuit boards, for example. Typical as a method of connecting a connection terminal of an FFC with a connection terminal of a board is a method that the connection terminals of the FFC and board are connected by: previously putting solder on the connection terminal of the board by a flow soldering process; then disposing the connection terminal of the FFC on the solder; and fusing the solder for each conductor of the connection terminal. The process of fusing solder to electrically connect connection terminals is often performed by hand using a soldering iron. Generally, the connection terminal of an FFC is composed of flat-plate-type copper wires plated with gold or tin, while the connection terminal of a board is composed of flux-coated copper plates or wires.

In addition to soldering as described above, laser welding, arc welding, conductive adhesives and the like have been examined as a means for forming an electrical connection between a connection terminal of an FFC and a connection terminal of a board.

KOKAI (Japanese Unexamined Patent Publication) No. 2002-359019 describes “an exposed-conductor portion of a flat cable and an unexposed-conductor portion connecting with the exposed-conductor portion are disposed on the insulating substrate of a printed board on an edge side thereof, and the unexposed-conductor portion is stack to the insulating substrate with an adhesive or the like and mechanically fixed thereto, while the exposed conductors of the flat cable are superposed on top faces of respective conductors arrayed in parallel on the top face of the printed board and electrically joined thereto by soldering or welding.”

### SUMMARY

To connect an FFC to a board efficiently, it is desired to collectively connect conductors. When an attempt to perform collective connection of an FFC is made using solder, there is a risk of fused solder causing a short circuit between adjacent conductors. Particularly, in the case of an FFC with a low-melting-point metal such as tin on its conductor surface, there is a risk of fusion of tin-plating likewise causing a short circuit even when no solder is used together.

The disclosure hereof provides a method of electrically connecting a connection terminal of an FFC and a connection terminal of a board and an electrically connected connection structure, which enable formation of a stable electrical connection superior in terms of production efficiency.

According to the disclosure hereof, a method of connecting a flexible flat cable and a board is provided, which includes the steps of: preparing the flexible flat cable having a first connection terminal composed of a plurality of exposed flat type conductors; preparing the board having a second connection terminal composed of a plurality of conductors; aligning each of the first and second connection terminals and placing an adhesive film on the first connection terminal; and thermocompressionally bonding the first and second connection terminals by heating and fusing the adhesive film while applying a pressure to the adhesive film, thereby sealing the first and second connection terminals, bringing each flat type conductor of the first connection terminal and the corresponding conductor of the second connection terminal into direct contact to form an electrical connection, and insulating adjacent ones of the plurality of flat type conductors of the first connection terminal by the adhesive film.

According to the disclosure hereof, a connection structure of a flexible flat cable and a board is provided, which includes: the flexible flat cable having a first connection terminal composed of a plurality of exposed flat type conductors; the board having a second connection terminal composed of a plurality of conductors, each conductor of the second connection terminal in direct contact with the corresponding flat type conductor of the first connection terminal forming an electrical connection; and an adhesive film sealing the first and second connection terminals, and insulating mutually adjacent ones of the plurality of flat type conductors of the first connection terminal.

According to the disclosure hereof, it is possible to directly form electrical connections between flat type conductors of the connection terminal of an FFC and conductors of the connection terminal of a board without using solder and in parallel to insulate FFC flat type conductors adjacent to each other. In addition, it is possible to protect the connection terminals of the FFC and board from the external environment by an adhesive film sealing the connection terminals.

The description above should not be regarded as disclosing all of the embodiments hereof and all advantages related herewith.

### BRIEF DESCRIPTION OF THE DRAWINGS

FIG. 1 is an exploded perspective view showing an outline of a method of connecting a flexible flat cable and a board according to an embodiment hereby disclosed. FIG. 2 is a cross-sectional view of a connection structure of an FFC and a board according to an embodiment hereby disclosed.

FIG. 3 is a cross-sectional view of a connection structure of an FFC and a board according to another embodiment hereby disclosed.

FIG. 4 is a cross-sectional view of a connection structure of an FFC and a board, which has a support material on an adhesive film.

FIG. 5 is a cross-sectional view of a connection structure according to an embodiment hereby disclosed, which is taken along a longitudinal direction of flat type conductors of an FFC.

FIG. 6 is a cross-sectional view of a connection structure according to another embodiment hereby disclosed, which is taken along a longitudinal direction of flat type conductors of an FFC.

### DETAILED DESCRIPTION OF THE PREFERRED EMBODIMENTS

Typical embodiments of the present disclosure will be described below in more detail with reference to the drawings for the purpose of illustration; however the disclosure is not limited to the embodiments.

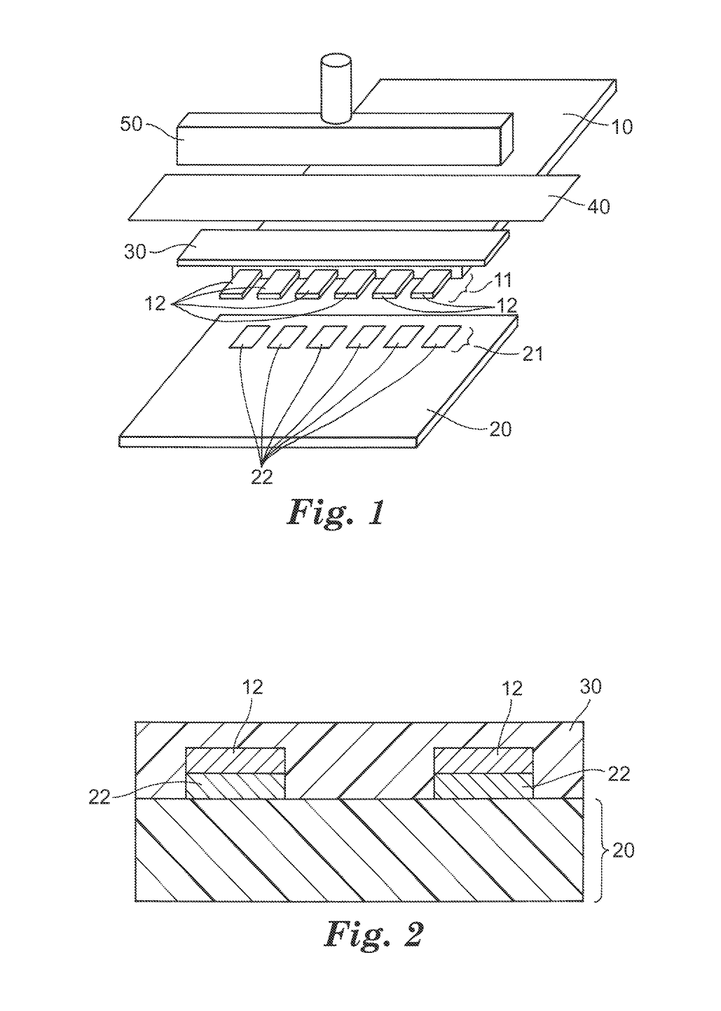

FIG. 1 schematically shows a method of connecting a flexible flat cable (FFC) and a board according to an embodiment hereby disclosed in an exploded perspective view. FFC 10 has a connection terminal 11 composed of a plurality of flat type conductors 12. The connection terminal 11 is an end portion of the flat type conductors 12 exposed by removing an insulating plastic film over and under the flat type conductor 12 from an end of the FFC to a fixed length. On the other hand, the board 20 to be connected with FFC 10 has a connection terminal 21 corresponding to the connection terminal 11 of FFC 10, and the connection terminal 21 is composed of a plurality of conductors 22 corresponding to the flat type conductors 12. The adhesive film 30 is disposed on the connection terminal 11 of FFC 10. The adhesive film 30 may cover the connection terminals 11 and 21 which have been aligned with each other. Further on the adhesive film 30, a buffer material 40 is disposed as required. The connection terminals 11 and 21 are bonded thermocompressionally using a thermocompression-bonding apparatus 50, in which heat and pressure are applied to the adhesive film 30 in parallel thereby to fuse the adhesive film.

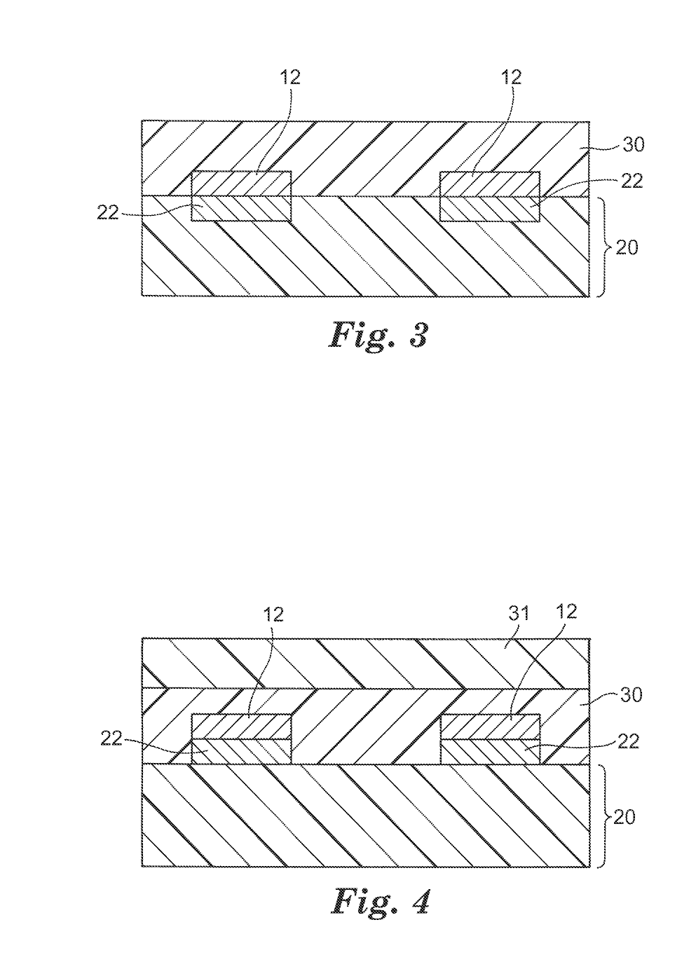

FIGS. 2 and 3 each show a connection structure of an FFC and a board thus connected in a cross-sectional view. The flat type conductors 12 and the corresponding conductors 22 are in direct contact. A “direct contact” refers to conditions in which two conductors have conductive materials (of e.g. copper or copper alloy) each forming a main portion of the conductor being in direct contact, or two conductors are in contact through coating materials e.g. tin- or gold-plating, which can be on surfaces of the conductors. Between each flat type conductor 12 and corresponding conductor 22, electrical connection is formed by a simple physical contact between the conductors, formation of a joint between the conductors by heating, or the like. For example, formation of a joint between conductors can be performed by heating and fusing tin-plating thereby to interpose the resultant fusion between the conductors. When heated, the adhesive film 30 fuses, develops fluidity, flows in between flat type conductors 12 adjacent to each other to insulate them, and covers the peripheries of the connection terminals 11 and 21 to seal off the terminals. As shown in FIG. 2, the conductors 22 may extend so that their connection face is above a surface of the board 20, i.e. the conductors 22 may protrude from the surface of the board 20. Alternatively, the connection face of the conductors 22 may be on the same plane as the surface of the board 20 as shown in FIG. 3. This is not shown in the drawing, however the connection face of the conductors 22 may be below the surface of the board 20, i.e. under the condition that the connection terminal 21 has a plurality of recesses, the connection face of the conductors 22 may be located in the recesses. In addition, the conductors 22 may be located inward from the periphery of the board 20 as shown in FIG. 1, or the conductors 22 may extend so that their ends reach the end of the board 20.

Generally, an FFC is a cable which includes flat type conductors arrayed at fixed intervals and insulating plastic films placed on top and bottom faces of the conductors, and which is made by applying heat and pressure to contact faces of the upper and lower plastic films thereby to thermally fusion-bond the films, or by gluing the films with an adhesive. Examples of such FFCs include Leafconn commercially available from Totoku Electric Co., Ltd., and a cable commercially available from Hitachi Cable Fine Tech, Ltd.

As shown in FIG. 1, the plurality of flat type conductors 12 constituting the connection terminal of FFC 10 have a flattened section such that the longer side makes the contact portion with the corresponding conductor 22, and they are arrayed side by side in a lateral direction. The flat type conductors 12 are exposed at an end portion of FFC 10 which a coating material is removed from and which corresponds to the portion of the connection terminal 11.

A general conductive material can be used for the flat type conductors. For example, a conductor made of copper or copper alloy may be used, and the conductor may be coated with tin, silver, gold, nickel, etc., to prevent the surface of the conductor from being oxidized. Particularly, a tin-coated copper wire made of copper or copper alloy having a surface coated with tin or the like can be used profitably because it is less expensive.

The flat type conductors have a flattened section, whose sectional shape and sectional size may be varied according to the use. Examples of the sectional shape of the flat type conductor include a shape differing in length between two directions substantially orthogonal to each other, e.g. a rectangle, a rectangle with the corners rounded and an ellipse. As shown in FIG. 1, when the major axis of sections of the flat type conductors is parallel to a direction along which the flat type conductors are arrayed, the flat type conductors are made harder to bend in the direction. On this account, in comparison to the case of using conductors having the same cross sectional area and a non-flattened section (e.g. a circular section), use of such flat type conductors makes the misalignment between the flat type conductors and board-side conductors less prone to occur in a direction in the plane of the board at the time of thermocompression bonding. The flat type conductors having a flattened section like this can be used advantageously in the method hereby disclosed without paying excessive attention to the misalignment with respect to board-side conductors.

In order to reduce the resistance of electrical connection in the case where the connection face of board-side conductors is flat, it is favorable to enlarge the area of contact to as much as possible under the condition that the sectional shape of the flat type conductors is substantially rectangular one. When doing so, the gap between the flat type conductors and board-side conductors can be made smaller. As a result, when the fused adhesive film flows to cover the flat type conductors and board-side conductors, voids (bubbles) created by the adhesive film not flowing into the gap can be reduced. When there are such voids, it is feared that the decrease in adhesion area deteriorates the adhesion strength, and the moisture in the voids and the expansion and contraction of voids caused by the change in temperature lead to the deterioration of reliability of connection portions. However, in some cases those problems can be avoided or remarkably reduced by use of the flat type conductors having a substantially rectangular section as stated above. In regard to the sectional size of the flat type conductors, for example, in the case of using them for general-purpose electronic devices, e.g. ink jet printer and copier machine, the shorter side may range from not less than about 0.01 or 0.03 mm to not more than about 0.15 or 0.12 mm. The longer side may range from not less than about 0.2 or 0.3 mm to not more than about 1.0 or 0.8 mm. The pitch of the flat type conductors may range not less than about 0.3 or 0.5 mm to not more than about 2.0 or 1.5 mm. As long as the sectional size and pitch take on these values, FFC flat type conductors can be connected with board-side conductors with a sufficiently low resistance of electrical connection, as well as when an adhesive film having a typical thickness is used, the connection terminals of the FFC and board can be sealed or glued reliably. Now, the longer side and shorter side herein stated mean a length thereof along a direction in which the section has a longest size (i.e. major axis), and a length in a direction substantially orthogonal thereto, respectively.

The board may be any appropriate board such as a paper board impregnated with resin, a glass-epoxy board, an aramid board, a bismaleimide-triazine (BT-resin) board, a glass or ceramic board which has a wiring pattern formed by ITO or metallic fine particles, a rigid circuit board like a silicon wafer having a joining portion of metallic conductor on its surface, or a flexible circuit board including a lead-type and via-type FPCs. In addition, a pattern of resist formed to define a connection terminal may be deposited on such boards. In applications to general-purpose electronic devices, a resin-impregnated paper board can be used in general because of its low cost.

The conductors constituting a connection terminal of a board may be of the same material as that of the flat type conductors of an FFC as described above. Further, a copper or copper alloy coated with flux may be used for the board-side conductors.

Generally, the pitch of board-side conductors is substantially the same as that of flat type conductors of an FFC. The width of board-side conductors may be substantially the same as that of flat type conductors of an FFC, and it may be changed appropriately in consideration of the resistance of electrical connection, stability, adhesion strength, restrictions in terms of device design, etc. Further, the connection face of board-side conductors may take on various shapes including plane-like and bump-like ones and the shape of a portion of the side face of a wire of conductor. However, a plane-like shape is advantageous because it enables the enlargement of the area of contact with FFC flat type conductors, reduction in the resistance of electrical connection, and increase in the adhesion strength. In addition, as stated above concerning the sectional shape of flat type conductors, it can be advantageous for avoiding or reducing the generation of voids that the connection face of board-side conductors is of a plane-like shape.

The adhesive film is made from a material which has an insulating property, and which softens or fuses and then develops fluidity when heated to a given temperature.

With such material, at the time of thermocompression bonding, FFC and board connection terminals can be sealed together, and thus the FFC can be connected with the board and concurrently, the flat type conductors can be insulated mutually by the material flowing into the gap between adjacent flat type conductors of the FFC. As to the viscosity of such adhesive film material, it is sufficient that the viscosity is adjusted within a range such that the material does not flow out excessively from a portion on which an attempt for connection is being made at a temperature in heating, and the material can go into the gap between the conductors when an appropriate pressure is applied thereto. In the case of connecting a tinned conductor, it is preferable for the purpose of preventing a short circuit between conductors that the adhesive is fluidized and fills the gap between adjacent conductors at a temperature below the one at which tin-plating fuses. It is preferable that the fluidized adhesive cures at least partially at the temperature at which tin-plating fuses. This may increase the adhesive power at an interface between the adhesive and the board, and therefore the possibility that tin-plating flows to short between the conductors can be decreased further.

For example, a thermosetting adhesive film containing a resin which fuses when heated to a given temperature, and then hardens when further heated can be used as the adhesive film. As the material of the thermosetting adhesive film like this, a thermosetting resin e.g. epoxy resin, phenol resin, polyurethane resin, unsaturated polyester resin, polyimide resin, urea resin, maleimide resin, (meth)acrylic resin, citraconimide resin or nadimide resin, can be used. Particularly, epoxy resin may be used because it is superior in film-forming property, heat resistance, adhesive power and other points. As the thermosetting adhesive film, a thermosetting adhesive film containing both thermoplastic and thermosetting components, e.g. a thermosetting adhesive film of SBS rubber, can be used.

In the case of an adhesive film using epoxy resin, a curing agent may be added to facilitate a curing reaction of the epoxy resin, as required. Examples of such curing agent include an amine curing agent, acid anhydride, dicyandiamide, cation polymerization catalyst, imidazole compound, and hydrazine compound.

As the adhesive film, a thermoplastic adhesive film or hot-melt adhesive film, which fuses when heated to a given temperature and hardens when cooled back to a temperature before heating, may be used. The material of such thermoplastic adhesive film may be a base polymer generally used for a hot-melt adhesive, e.g. styrene phenol, ethylene-vinyl acetate copolymer, low-density polyethylene, ethylene-acrylate copolymer, polypropylene, styrene-butadiene block copolymer, styrene-isoprene copolymer and phenoxy resin.

To these adhesive films, organic or inorganic filler may be added for improvement of the film strength and/or control of the fluidity. Further, other components, e.g. an antioxidant, a stabilizer, a plasticizer, an antistatic agent and a fire retardant may be added.

The adhesive film may further include a support material or backing material disposed on a face opposite to a face oriented toward the connection terminal of an FFC at the time of thermocompression bonding as required. The support material herein refers to a material which does not fuse at the time of thermocompression bonding, and thereafter remains on the adhesive film, and is able to continue providing mechanical support and/or protection. Further, the backing material herein refers to a material attached to one side of the adhesive film for the purpose of handling of the adhesive film, which is removed, or thermocompressionally bonded and fused together with the adhesive film thereby to lose at least part of its shape, at the time of thermocompression bonding.

As such a support material, a resin film having a high heat resistance and superior in flexibility can be used. Examples of such resin film include e.g. a polyamide-based resin film, a polyimide-based resin film of polyimide, polyamideimide or the like, and a film of polyethylene naphthalate. Particularly, in the case where the temperature at the time of thermocompression bonding is high, a polyimide-based resin film can be used profitably. As a result of using a support material, when the adhesive film is used, for example, in a location where it is likely to be stressed or repeatedly bent, the adhesive film can be provided with a further mechanical support and therefore the adhesive film can be made difficult to be damaged. In addition, when the adhesive film is used under a severe external environment, e.g. a high humidity environment, the adhesive film can be prevented from being directly exposed to an external environment and thus degraded. In FIG. 4, a cross-sectional view shows an example of the connection structure of an FFC and a board, which has a support material 31 on the adhesive film 30.

As the backing material, a release liner temporarily supporting the adhesive film, e.g. a PET film which has a releasing surface processed with silicone, can be used. The backing material may be removed before thermocompression bonding after the adhesive film is placed on the connection terminal. Alternatively, the backing material may be thermocompressionally bonded together with the adhesive film as long as it does not negatively affect the performances of the resultant electrical connection. In the case, the backing material fuses and mixes with at least part of the adhesive film, and its shape is lost at least partially. When using a backing material, e.g. an adhesive film which has a low shape-retention property because of its extremely small thickness or large flexibility, or an adhesive film which exhibits a large adhesion at a room temperature and is hard to handle can be applied to the method hereby disclosed.

The alignment between the connection terminals of the FFC and board may be performed by a method commonly used for FFC electrical connections. For example, the alignment may be performed visually or through image recognition using a microscope or the like so long as markers are put on the connection terminals or other portions other than the terminals. After that, an adhesive film, which has been prepared to have dimensions suitable for covering the FFC and board connection terminals, can be placed on the connection terminals of the FFC. Typically, the adhesive film is disposed so that it covers the end portion of the FFC covering together with the connection terminal to prevent the FFC connection terminal from being exposed. Thus, a stack having the adhesive film, FFC connection terminal and board connection terminal are arranged from the top in this order is formed.

On the stack, a buffer material may be disposed further as required. The buffer material serves to prevent the damage owing to the pressure by the thermocompression-bonding apparatus locally applied to the stack and to more evenly fluidize the adhesive film. The buffer material can be useful for preventing the sticking between the thermocompression-bonding apparatus and the adhesive film. Examples of the buffer material used commonly include a film having both heat resistance and releasability, i.e. a polytetrafluoroethylene film having a thickness of 20 to 100 μm.

Next, the thermocompression-bonding apparatus is set above the stack formed as described above, which includes the adhesive film, FFC connection terminal, and board connection terminal, and the buffer material disposed on it as required. Then, the thermocompression-bonding apparatus is moved downward to conduct the thermocompression bonding of the stack, whereby the adhesive film is heated and fused while a pressure toward the FFC and board connection terminals is applied. At this time, the fused adhesive film covers the FFC and board connection terminals all together, and flows into a gap between adjacent flat type conductors. In the case of using a thermosetting adhesive film, after the adhesive film has softened once, the adhesive film is hardened when heated continuously. When the adhesive film is cured after an elapsed of a given time, application of a pressure and heat by the thermocompression-bonding apparatus is stopped, followed by cooling to a room temperature. In the case of using a thermoplastic adhesive film, the fused adhesive film covers the FFC and board connection terminals, and flows into a gap between adjacent flat type conductors. At this time, cooling is started while the connection terminals are kept in contact with each other. Then, after the adhesive film is cooled and hardened to the point where it can keep the connection state, the application of pressure by the thermocompression-bonding apparatus is stopped, and then the connection is completed.

As the thermocompression-bonding apparatus, available ones include a bonder termed a pulse-heat bonder such as a ceramic heat bonder which can apply a pressure and perform pulse-mode heating. A thermocompression-bonding apparatus like this is available from e.g. Nippon Avionics Co., Ltd. under the model number TCW-125B, or Ohashi Engineering Co., Ltd. under CT-300.

The temperature and pressure in thermocompression bonding may be decided in consideration of various factors including the fusing temperature and/or curing temperature of an adhesive film to be used, and the presence or absence of a join formed between the flat type conductor and board-side conductor. Generally, on the basis of the effective adhering region of the adhesive film, the pressure at the time of thermocompression bonding may range from not less than about 0.1 or 0.5 MPa to not more than about 4 or 2 MPa. In addition, the temperature at the time of thermocompression bonding may take on any value as long as the adhesive film can be fused under the pressure applied at the time of compression-bonding, and the temperature may be not less than about 70 or 100° C. Further, in the case where a connection between conductors to be electrically connected is formed by fusing a coating material such as plating on the surface of the conductors, it is possible to conduct heating to the fusing temperature of the plating or higher. On the other hand, to prevent the thermal decomposition of the adhesive film and the damage to the board and the FFC covering, the temperature at the time of thermocompression bonding may be set to not more than about 350 or 330° C. In the case of using a thermosetting adhesive film, a post-cure (after-cure) may be performed at about 150 to 250° C., for example.

Thus, the connection terminals of the FFC and board are sealed by the cured or re-hardened adhesive film. The adhesive film encloses the connection terminals of the FFC and board as a whole and uninterruptedly thereby to protect them from an external environment. The adhesive film attaches to portions other than the connection terminal of the board, namely a surrounding of the connection terminal of the board and a gap between the conductors, whereby the FFC thus enclosed is fixed to the board. In the present disclosure, as the conductors constituting the connection terminal of an FFC are flat-plate-type ones, the adhesive film spreads substantially in parallel with the upper plane defined by the flat type conductors, and its thickness is more uniform in comparison to the case of using conductors circular in section. Therefore, it is possible to reduce the occurrence of an electrical connection-related failure attributed to e.g. that the adhesive film cannot protect a certain conductor or a certain portion of a conductor sufficiently because the film is locally thinner in thickness on the certain conductor or portion.

The FFC flat type conductors and board-side conductors form electrical connection in direct contact with each other, which require neither additional solder nor conductive adhesive therebetween. For example, when the flat type conductors are gold-plated ones, only a physical contact with the board-side conductors likewise plated with gold or coated with flux can establish an electrical connection. Alternatively, for example, in the case of using tin-coated flat type conductors plated with tin, tin-containing joints can be formed between the flat type conductors and board-side conductors by heating the stack at a relatively high temperature as high as the fusing temperature of the tin coating, e.g. about 320° C. The electrical connection that the FFC flat type conductors and board-side conductors are in direct contact with each other can be formed by joint formation in which a coating material is interposed between the flat type conductors and board-side conductors in this way. In this case, the joint thus formed can also contribute to the improvement of the adhesion strength of the FFC and board. Further, according to the embodiment like this, the heating to the fusing temperature of tin coating can be conducted in the condition that the flat type conductors and board-side conductors are almost entirely sealed by the adhesive film without being exposed, namely the conductors are shut off from outside air. Therefore, it is possible to reduce the occurrence of whisker which often becomes a problem with tin-coated conductors.

Further, the method of conducting thermocompression bonding with a non-conductive adhesive film placed between a connection terminal of a cable and a connection terminal of a board needs a high pressure in compression bonding in order to eject the adhesive from between the conductors. In contrast, the method hereby disclosed does not require the ejection of the adhesive from between the conductors, and allows connection terminals of the cable and board to be connected with each other with a relatively low pressure and a relatively low temperature. Therefore, the method hereby disclosed can be used particularly suitably to connect a cable having flat type conductors with flat contact faces and large contact areas with mating conductors.

In addition, the method hereby disclosed makes it possible to insulate mutually adjacent flat type conductors of an FFC, and therefore the short circuit between the conductors, which is prone to occur at the time of connecting an FFC with a board by solder, can be averted. Besides, the method hereby disclosed enables two or more conductors to be connected at a time, and therefore, it can contribute to the increase in the production efficiency of electronic devices.

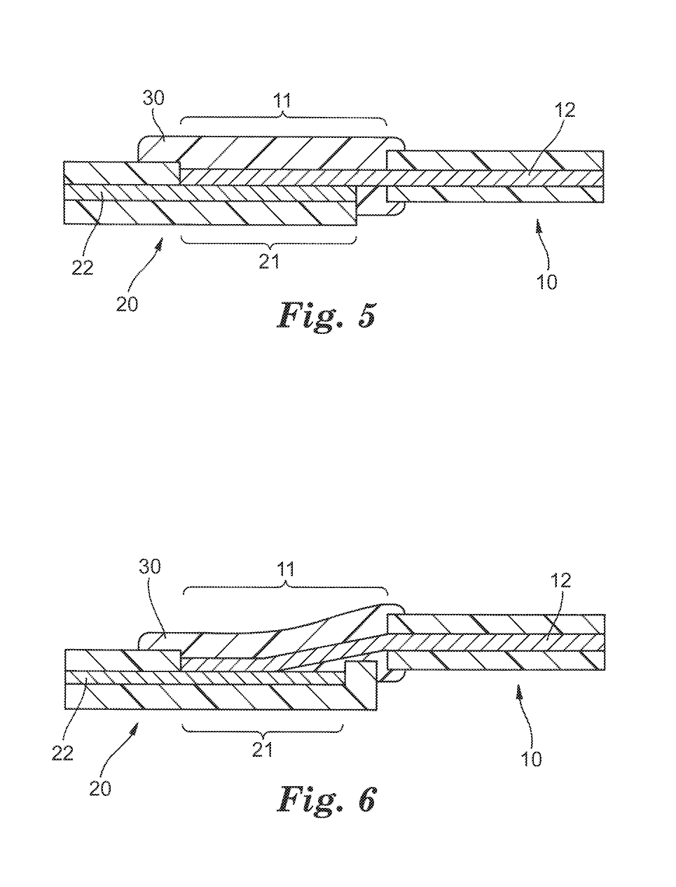

FIGS. 5 and 6 show an example of the connection structure of an FFC and a board achieved by the method hereby disclosed in sectional views different from FIGS. 2 and 4, i.e. vertical sectional views taking along a lengthwise direction of the flat type conductors of the FFC. However, the connection structure according to the disclosure is not limited to them.

Referring to FIG. 5, as to the connection terminal 21 of the board 20, the conductor 22 extends to an end of the board 20. In regard to the connection terminal 11 of FFC 10, the flat type conductor 12 is exposed by a length somewhat longer than the connection terminal 21. The adhesive film 30 is squeezed in between flat type conductors 12 at the time of thermocompression bonding, and is also spread on the underside of the flat type conductor 12.

Referring to FIG. 6, as to the connection terminal 21 of the board 20, the conductor 22 is placed at a level fallen from the top face of the board 20. The flat type conductor 12 is bent lightly and comes into contact with the conductor 22 from a halfway point of the connection terminal 11 of FFC 10. The connection terminals 11 and 21 are sealed by the adhesive film 30. In comparison to a conductor having the same cross sectional area and a circular section, it is easier to lightly bend the flat type conductor 12, i.e. a conductor of FFC 10, in a direction of the thickness in which the size of the conductor is smallest and bring the flat type conductor into contact with the surface of the conductor 22 of the board 20 in this way.

As is clear from the drawings, the adhesive film 30 seals the connection terminal 11 of FFC 10 and connection terminal 21 of the board 20 almost entirely, and therefore the connection terminals 11 and 21 are not exposed to the outside. Thus, the possibility that e.g. the moisture coming from the outside enters interfaces between the adhesive film 30 and connection terminals 11 and 21 to cause the reduction in reliability can be decreased.

The connection structures according to the disclosure hereof have been exemplarily described with reference to FIGS. 5 and 6. However, various connection structures can be constructed by changing: the alignment of the FFC and board to a vertical direction; the length of exposed flat type conductors of the FFC; the height at which the board-side conductors are located; and the length of exposed board-side conductors, etc.

The method and connection structure according to the disclosure hereof can be applied to various electronic devices using FFCs, e.g. ink jet printers, copier machines, stereos, television sets, VTRs, telephone sets and fax machines.

### EXAMPLES

The typical examples hereof will be described below in detail. However, it is obvious to those skilled in the art that changes and modifications of the following examples may be made within the claims hereof.

### 1. Sample and Apparatus

Bonder: Pulse-heat bonder CT-300 (manufactured by Ohashi Engineering Co., Ltd.) (Head size of contact face: 3 mm×4 cm)

Adhesive Film:

(A) Epoxy-based thermosetting adhesive film (Item No. 7132, manufactured by Sumitomo 3M Ltd., Size: 6 mm×3 mm, Thickness: 30 μm)

(B) (A)+Support material (25-um-thick polyimide film with the same size) Board: Resin-impregnated paper board (Board size: 5 cm×5 cm, Connection terminal portion: 6 mm×2.5 cm, Conductor width of connection terminal: 0.6 mm, Distance between conductors: 0.4 mm, Conductor pitch: 1 mm, Number of conductors: 25)

Conductor Material on Board: flux-coated copper plate

Flexible Flat Cable: Length of exposed flat type conductor: 4 mm, Conductor thickness of exposed portion: 0.1 mm, Conductor Width: 0.6 mm, Distance between conductors: 0.4 mm, Conductor pitch: 1 mm, Number of conductors: 25.

Conductor Material of Flexible Flat Cable: Tin-plated copper

Material for Buffer at Thermocompression Bonding: Polytetrafluoroethylene film (Size: 5 cm×1 cm, Thickness: 50 μm)

2. Connection Method

1) Putting a resin-impregnated paper board on a stage of the bonder.

2) Aligning the exposed connection terminal of an FFC with the connection terminal of the paper board from above.

3) Using a tape to fix the FFC and paper board by portions other than the connection terminals.

4) Putting an adhesive film on the exposed connection terminal of the FFC.

5) Putting a polytetrafluoroethylene film used as a buffer material on the adhesive film.

6) Bring down a bonding head to apply a load of 10 kgf, and performing thermocompression bonding according to a heating profile such that the temperature reaches from a room temperature to 320° C. in 10 seconds while keeping the pressure applied to an effective adhering region of the adhesive film 1.3 MPa. At the point of time when the temperature reaches 320° C., the head is brought up to release the pressure. In this step, the adhesive film cures, whereby the FFC is connected to the board. In parallel, tin plating is fused, and thus flat type conductors of the FFC and conductors of the board are joined to each other.

3. Results

In both the cases of using adhesive films of (A) and (B), no short circuit between adjacent flat type conductors of the FFC was found, and a good electrical connection between the FFC connection terminal and board connection terminal was established. The connection terminals of the FFC and board were sealed by the adhesive film, and the FFC and board were connected with a practically sufficient strength. In the case of using the adhesive film of (B), the sealed portions of the FFC and board connection terminals were further sealed by the polyimide film.

1. A method of connecting a flexible flat cable and a board, comprising the steps of:
preparing the flexible flat cable having a first connection terminal composed of a plurality of exposed flat type conductors;
preparing the board having a second connection terminal composed of a plurality of conductors;
aligning each of the first and second connection terminals and placing an adhesive film on the first connection terminal; and
thermocompressionally bonding the first and second connection terminals by heating and fusing the adhesive film while applying a pressure to the adhesive film, thereby sealing the first and second connection terminals, bringing each flat type conductor of the first connection terminal and the corresponding conductor of the second connection terminal into direct contact to form an electrical connection, and insulating adjacent ones of the plurality of flat type conductors of the first connection terminal by the adhesive film.

2. The method of claim 1, wherein each flat type conductor of the first connection terminal is a tin-coated copper wire.

3. The method of claim 1, wherein each flat type conductor of the first connection terminal has a flattened section measuring 0.01 to 0.15 mm in shorter side, and 0.2 to 1.0 mm in longer side, and a pitch of the plurality of flat type conductors is between 0.3 and 2.0 mm inclusive.

4. The method of claim 1, wherein the adhesive film further includes a support material or backing material disposed on a face opposite to a face of the adhesive film oriented toward the first connection terminal.

5. The method of claim 1, wherein the support material is a polyimide-based resin film.

6. A connection structure of a flexible flat cable and a board comprising:
the flexible flat cable having a first connection terminal composed of a plurality of exposed flat type conductors;
the board having a second connection terminal composed of a plurality of conductors, each conductor of the second connection terminal in direct contact with the corresponding flat type conductor of the first connection terminal forming an electrical connection; and
an adhesive film sealing the first and second connection terminals, and insulating mutually adjacent ones of the plurality of flat type conductors of the first connection terminal.

7. The connection structure of claim 6, wherein each flat type conductor of the first connection terminal is a tin-coated copper wire.

8. The connection structure of claim 6, wherein each flat type conductor of the first connection terminal has a flattened section measuring 0.01 to 0.15 mm in shorter side, and 0.2 to 1.0 mm in longer side, and
a pitch of the plurality of flat type conductors is between 0.3 and 2.0 mm inclusive.

9. The connection structure of claim 6, wherein the adhesive film further includes a support material composed of a polyimide-based resin film disposed on a face thereof opposite to the first and second connection terminals.
